(19) United States
(12) Patent Application Publication
(10) Pub. No.: US 2007/0040621 A1
(43) Pub. Date: Feb. 22, 2007

(54) Voltage controlled oscillator using dual gated asymmetrical FET devices

(76) Inventors: Hung C. Ngo, Austin, TX (US); Ching-Te Chuang, South Salem, NY (US); Keunwoo Kim, Somers, NY (US); Jente B. Kuang, Austin, TX (US); Kevin J. Nowka, Georgetown, TX (US)

Correspondence Address: IBM CORP (WSM);C/O WINSTEAD SECHREST & MINICK P.C., PO BOX 50784, DALLAS, TX, 75201, US

(21) Appl. No.: 11/204,412

(22) Filed: Aug. 16, 2005

(51) Int. Cl. H03K 3/03

(52) U.S. Cl. 331/57

(57) ABSTRACT

A ring oscillator is formed using inverting stages configured from asymmetrical dual gated FET (ADG-FET) devices. The simplest form uses an odd number of CMOS inverter stages configured with an ADG-PFET and an ADG-NFET. The front gates are used as the logic inputs and are coupled to preceeding outputs from the main ring. The back gates of the ADG-PFET devices are coupled to a first control voltage and the back gates of the ADG-NFET devices are coupled to a second control voltage that is the complement of the first control voltage referenced to an off-set voltage. Other configurations of logic inverting stages using ADG-FET devices may also be used. The control voltage is varied to modulate the current level set by the logic state at the inputs coupled to the front gates.

### GOVERNMENT RIGHTS

This invention was made with Government support under PERCS II, NBCH3039004. THE GOVERNMENT HAS CERTAIN RIGHTS IN THIS INVENTION.

### TECHNICAL FIELD

The present invention relates in general to complementary metal oxide semiconductor (CMOS) circuits for implementing a very high frequency voltage controlled oscillator (VCO).

### BACKGROUND INFORMATION

Phase-locked loops (PLLs) have been widely used in high-speed communication systems because PLLs efficiently perform clock recovery or clock generation at a relatively low cost. Dynamic voltage and frequency scaling is a critical capability in reducing power consumption of power sensitive devices. Scaling, in this sense, means the ability to select high performance with nominal power supply voltages and high frequency clock operation or low performance by reducing the power supply voltage and corresponding the clock frequency. Reducing the system power is usually done when performance is not needed or when running from a limited energy source such as a battery. To allow low power operation, the PLL and other circuits must support very aggressive power/energy management techniques. For the PLL, this means low power operation while supporting key required features such as dynamic frequency scaling, dynamic voltage scaling, clock freezing and alternate low frequency clocking. Dynamic implies that the PLL is able to support changes in the output frequency and logic supply voltage without requiring the system to stop operation or waiting for the PLL clock to reacquire lock.

Using a PLL or delay-locked loop (DLL) has advantages in a battery powered system because a PLL is able to receive a lower reference frequency from a stable oscillator to generate system clock frequencies. A PLL also allows changing the system clock frequency without changing the reference frequency. The prior art has described ways of selecting operating points of voltage and frequency statically, for example, stopping execution while allowing the PLL to frequency lock to a new frequency. This slows system operations and complicates system design.

One of the key circuits in a PLL is a voltage-controlled oscillator (VCO). Circuits in the PLL generate an error voltage that is coupled to the VCO to control the frequency of the VCO output. By frequency dividing the output of the PLL and feeding it back and comparing it to a low frequency crystal-controlled reference clock, a stable high frequency clock may be generated. The VCO in a PLL typically has a range over which the frequency of the VCO may be voltage-controlled. In systems employing frequency scaling, it is desirable to have a voltage-controlled frequency range for normal voltage operation and another voltage-controlled frequency range for low voltage operation without resorting to two VCOs.

The VCO circuit is sometimes considered the most difficult circuit to implement in the PLL especially if ultra high frequencies and low jitter are required. Typically, the VCO is made using five or more inverting elements in a ring oscillator configuration. Standard ring oscillator topologies are relatively simple to design, have low-power, and have robust noise margins. The main drawback to the ring oscillator is that many stages are required to generate high quality signals and many stages lead to lower frequencies.

The requirements for high frequency VCOs are becoming more demanding and in some cases the shortest ring oscillator of three stages may not produce sufficiently high frequencies. A number of circuit topologies have been developed to improve the frequencies possible with the ring oscillator. One such circuit topology is the “classic interpolator” as seen in FIG. 1A and FIG. 1B. Another circuit topology is the “phased oscillator” design shown in FIG. 2A and FIG. 2B. Both of these circuit topologies provide a frequency boost to the standard ring oscillator but both are limited to five or more oscillator stages. In most cases, these oscillator circuit topologies produce frequencies in the range of a standard three stage ring oscillator.

Making a ring oscillator voltage controlled usually requires the use parallel or interpolation stages that are coupled with pass gates that are modulated with a control voltage. This requires more devices and more complex circuit topologies.

Therefore, there is a need for a way of configuring a ring VCO that have single devices in the main path that can be voltage controlled.

### SUMMARY OF THE INVENTION

A ring oscillator is configured using inverters in a series connection with the output of the last stage feeding back and driving the input of the first stage. The FET devices used to implement the inverters comprise P and N channel FET devices with asymmetrical dual gates. The front gates are used for the main ON/OF switching of the ring. The back gates are configured to modulate the current produced by the front gates. The back gates are coupled to a common control voltage which is varied to modulate the current drive of the front gates thus varying the frequency of the ring oscillator and thus forming a VCO worth minimal devices. Since there are no secondary devices for parallel or feed-forward paths the capacitance loading is reduced and the frequency range of the VCO is increased.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a circuit diagram of a slow path and a parallel fast path used in prior art ring oscillators;

FIG. 1B is a circuit diagram of a 5-stage inverter ring oscillator wherein each group of 3 inverters are bypassed with a single fast path inverter;

FIG. 2A is a circuit diagram of a phased feedback ring oscillator used in the prior art;

FIG. 2B is a circuit diagram illustrating how the phased feedback of FIG. 2A is implemented in a 5-stage inverter ring oscillator;

FIG. 3A is a circuit diagram of a conventional NAND logic gate implemented with dual gated FET devices configuring a dual gated NAND (DG-ND) gate allowing voltage control of current drive;

FIG. 3B is a circuit diagram of a conventional NOR logic gate implemented with dual gated FET devices configuring a dual gated NOR (DG-NR) gate allowing voltage control of current drive;

FIG. 4A is a circuit block diagram of a VCO according to embodiments of the present invention;

FIG. 4B is a circuit block diagram of a VCO according to another embodiment of the present invention;

FIG. 4C is a circuit block diagram of a VCO according to another embodiment of the present invention;

FIG. 4D is a circuit diagram of a VCO implemented with DG-ND logic gates where the second input is used as a gate input according to embodiments of the present invention;

FIG. 4E is a circuit diagram of a VCO implemented with DG-NR logic gates where the second input is used as a gate input according to embodiments of the present invention;

FIG. 4F is a circuit block diagram of a VCO implemented with DG-ND logic gates configured as latches for generating an output and an in-phase complementary output according to embodiments of the present invention;

FIG. 5; is a circuit diagram of a circuit suitable for generating control voltages for the VCO of FIG. 4; and

FIG. 6 is a block diagram of a phase locked loop (PLL) suitable for practicing embodiments of the present invention.

### DETAILED DESCRIPTION

In the following description, numerous specific details are set forth to provide a thorough understanding of the present invention. However, it will be obvious to those skilled in the art that the present invention may be practiced without such specific details. In other instances, well-known circuits may be shown in block diagram form in order not to obscure the present invention in unnecessary detail. For the most part, details concerning timing, and the like have been omitted inasmuch as such details are not necessary to obtain a complete understanding of the present invention and are within the skills of persons of ordinary skill in the relevant art.

Refer now to the drawings wherein depicted elements are not necessarily shown to scale and wherein like or similar elements are designated by the same reference numeral through the several views.

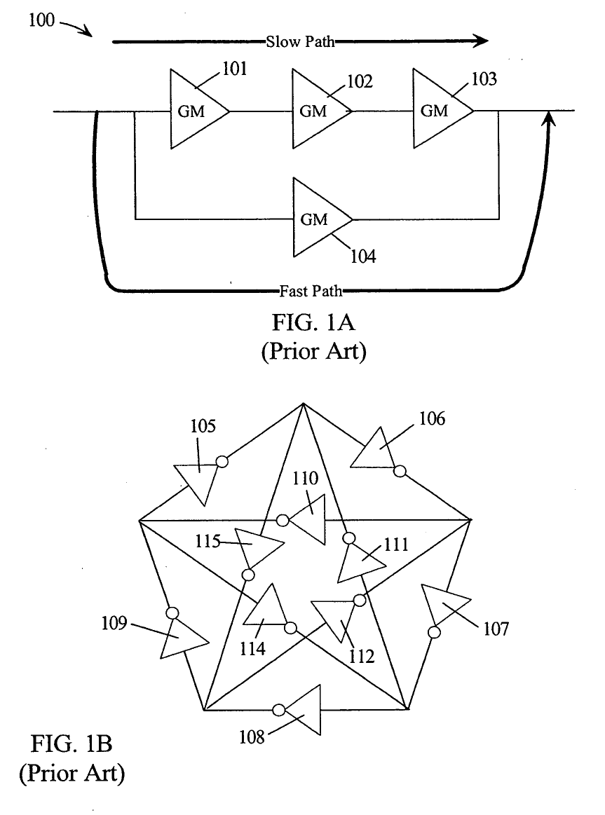

FIG. 1A illustrates an inverting stage 100 comprising a fast path with inverter 104 and a slow path with inverters 101-103. Typically, the fast path inverter 104 has some form of voltage control to set its delay. In this manner, the combined delay through the parallel path may be modulated. A logic transition on the output is the combined response of inverter 103 and 104.

FIG. 1B is a circuit diagram of a 5-stage inverter ring oscillator using the parallel fast paths and slow paths of FIG. 1A. Each group of 3 inverters in the outer ring is bypassed by a single inverter in the inner path. Inverters 105-107 are bypassed with inverter 114, inverters 106-108 are bypassed by inverter 115, inverters 107-109 are bypassed by inverter 110, inverters 108-109 and 105 are bypassed by inverter 111, and inverters 109 and 105-106 are bypassed with inverter 112.

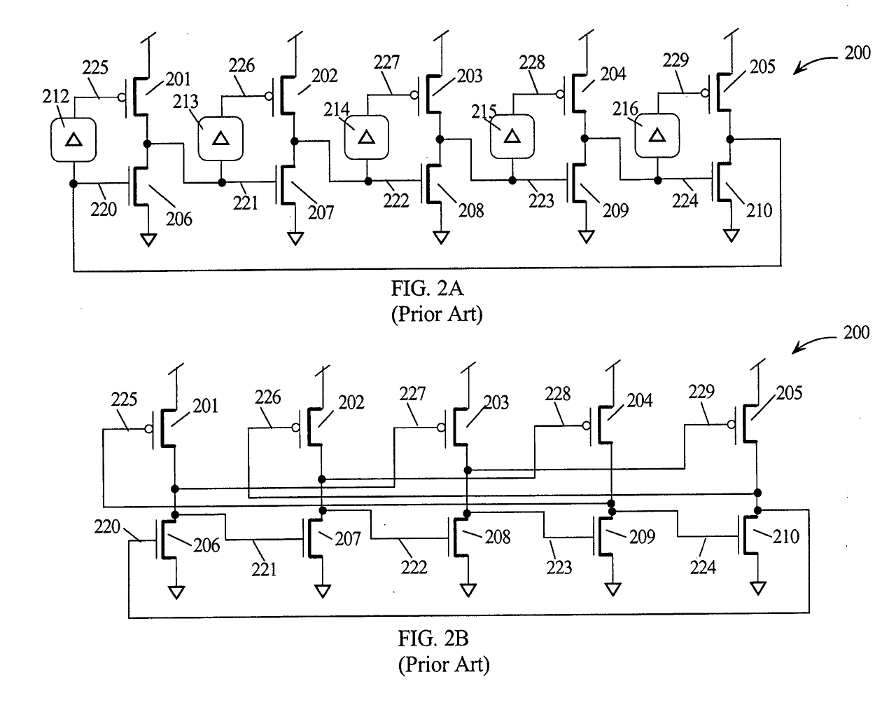

FIG. 2A is a circuit diagram of phased feedback 5-stage inverter ring oscillator used in the prior art. PFETS 201-205 and corresponding NFETS 206-210 form the inverting stages wherein the gate drive for the PFETS and the NFETS of the same stage are driven by different signals. Delay blocks 212-216 illustrate that the signals that turn the NFETS ON and turn the PFETS OFF a delay time later. Inputs 220-224 are delayed to produce inputs 225-229.

FIG. 2B illustrates connections that implement the topology of FIG. 2A. When an NFET turns ON, then a delayed signal is generated that turns OFF its series coupled PFET at a later time. A logic one transition on the node 220 of NFET 206 turns NFET 206 ON but does not turn PFET 201 OFF until a delay time later (as set by the delay of 212). Therefore, the gate 225 of PFET 201 must be at a logic zero, in which case both PFET 201 and NFET 206 are ON at the same time. These two devices will operate in an analog mode during this time period with the transition state on node 221 determined by the relative impedances of the ON devices PFET 201 and NFET 206. When node 221 eventually falls below the threshold voltage of NFET 207, then NFET 207 will turn OFF. In this case, PFET 202 is OFF and will turn ON a delay time later determined by delay block 213. For the delay period of delay block 213, both NFET 207 and PFET 202 are OFF. The alternate “analog” logic one and logic zero states propagate through outputs 222-224 and delay blocks 214-216. The assumed logic one transition of gate 220 propagates as a logic one transition on node 224 which turns ON NFET 210 and causes node 220 to transition to the opposite of the assumed state.

No matter what output state is assumed, traversing through the forward delay path will yield a logic state that changes the assumed state. This is true for P and N channel devices which in each stage are coupled to different gate control signals. This circuit topology will give good results; however, it does not have a phase synchronous complementary output and it is limited to 5 stages because each stage feeds back from 3 stages ahead which requires 4 stages and the overall circuit must be inverting so it requires 5 stages.

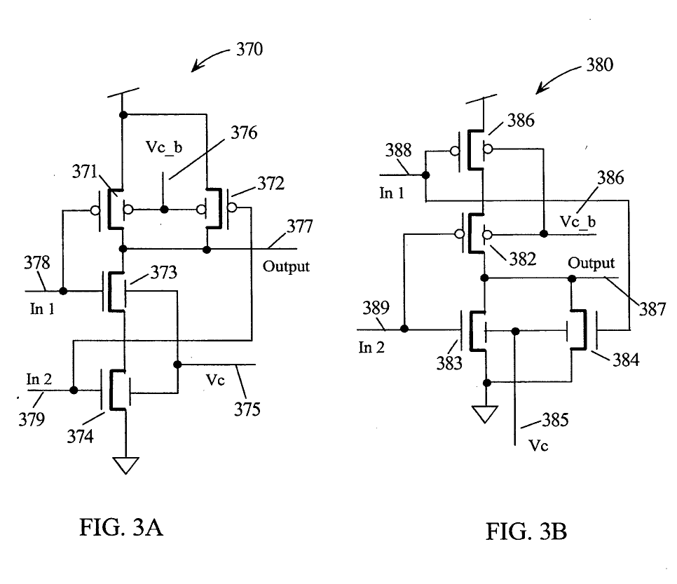

FIG. 3A is a circuit diagram of a two input dual gate FET implemented NAND (DG-N) gate 370, according to embodiments of the present invention, where the back gates of the DG-FET devices are used to modulate the drive current when the logic inputs are logic one and a logic zero states. DG-ND gate 370 is configured like a conventional NAND gate except that the back gates of the DG-FET devices are coupled to control voltages instead of logic inputs. To facilitate better operation in this mode, ADG-FET devices are used in place of symmetrical DG-FET devices. DG-PFET devices 371 and 372 charge output 377 with a current level modulated by the level of control voltage Vc_b 376 when either of their front gates is a logic zero state. Likewise, DG-NFET devices 373 and 374 discharge output 377 with a current level modulated by the level of control voltage Vc 375 when both of their front gates are a logic one state.

FIG. 3B is a circuit diagram of a two input dual gate FET implemented NOR (DG-NR) gate 380, according to embodiments of the present invention, where the back gates of the DG-FET devices are used to modulate the drive current when the logic inputs are logic one and a logic zero states. DG-NR gate 380 is configured like a conventional NOR gate except that the back gates of the DG-FET devices are coupled to control voltages instead of logic inputs. To facilitate better operation in this mode, ADG-FET devices are used in place of symmetrical DG-FET devices. DG-PFET devices 381 and 382 charge output 387 with a current level modulated by the level of control voltage Vc_b 386 when both of their front gates are a logic zero state. Likewise, DG-NFET devices 383 and 384 discharge output 377 with a current level modulated by the level of control voltage Vc 385 when either of their front gates is a logic one state.

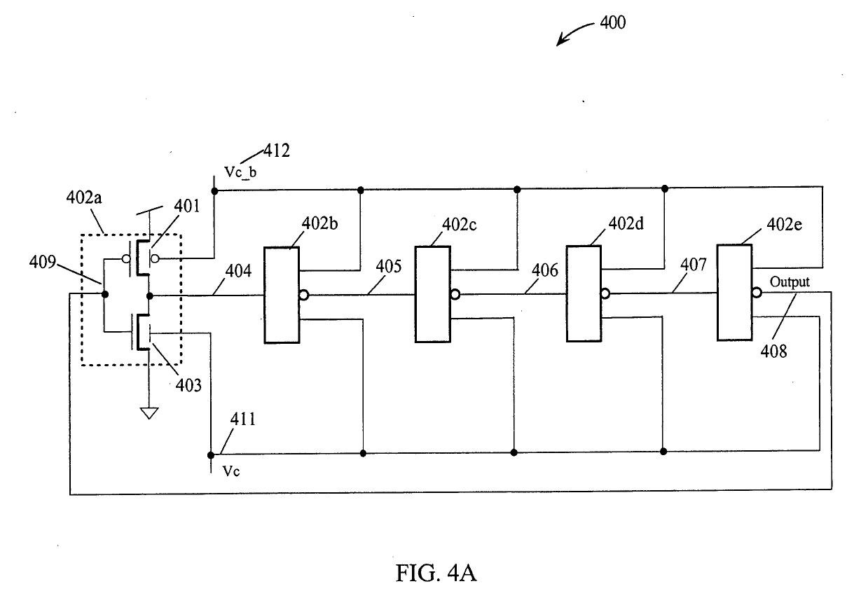

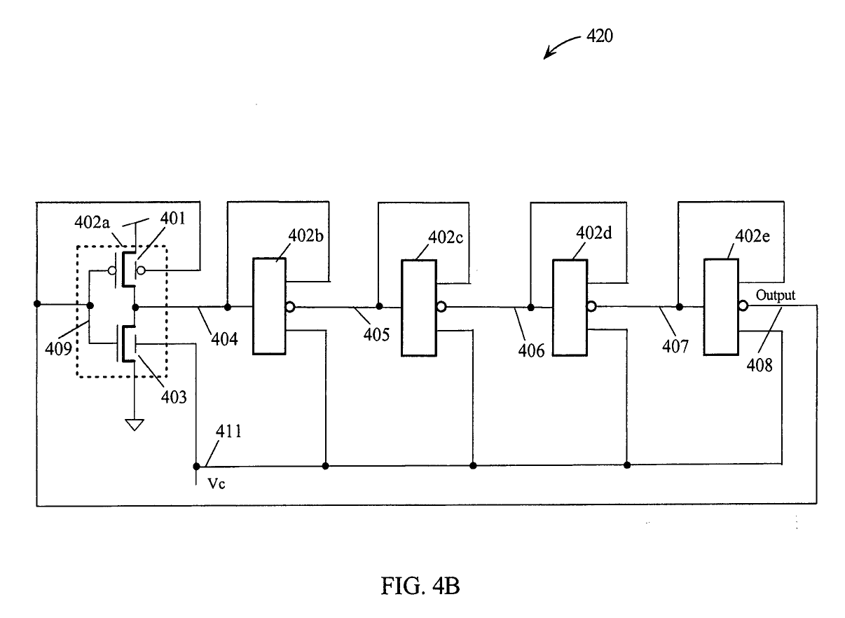

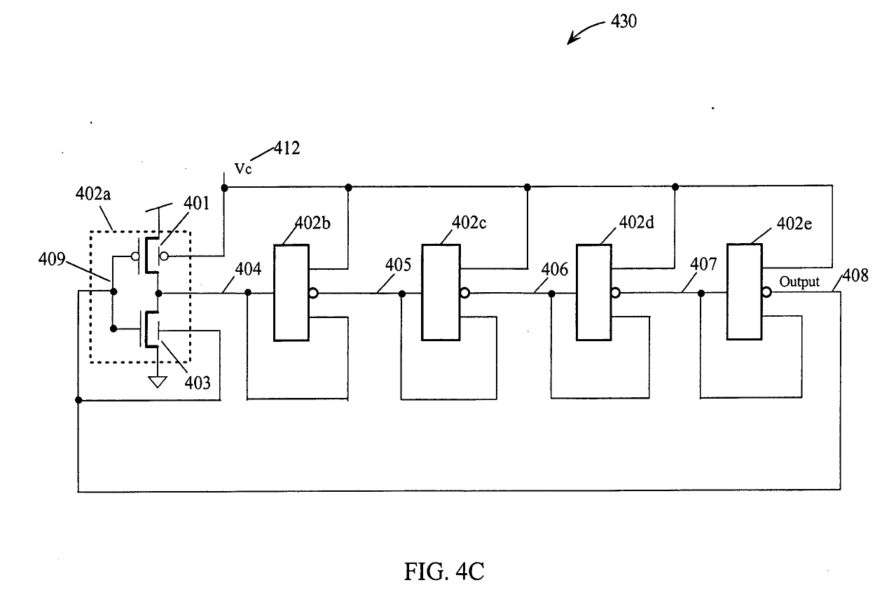

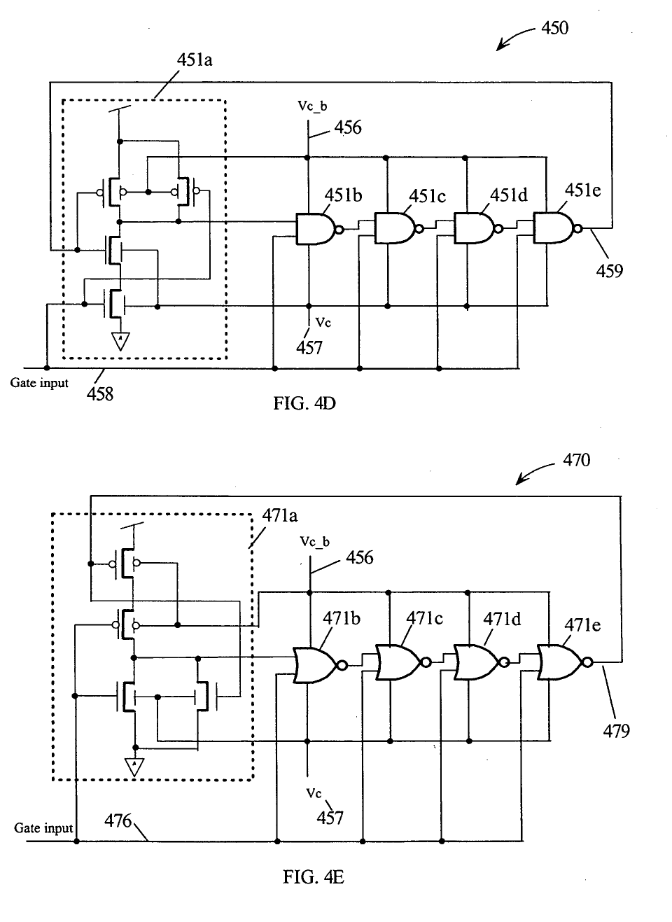

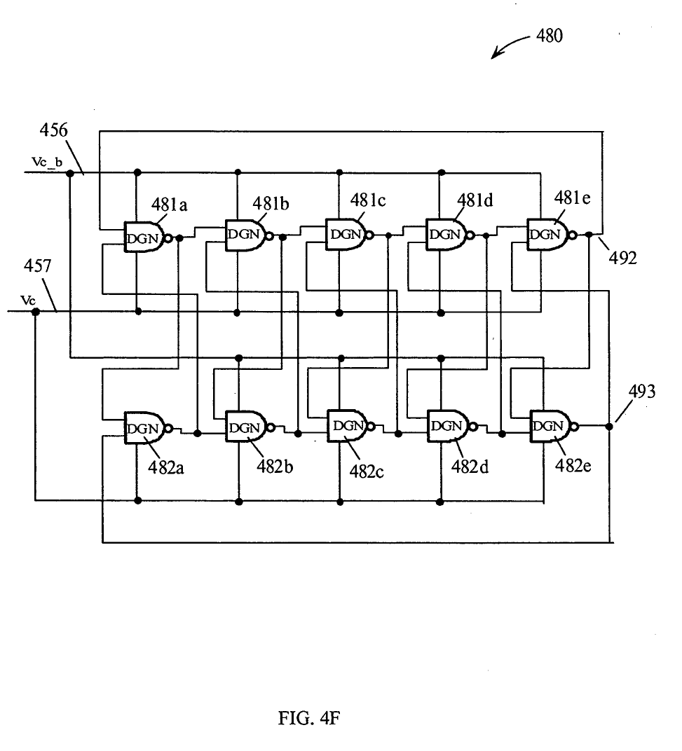

FIG. 4A is a circuit block diagram of VCO 400 according to embodiments of the present invention. Exemplary inverting stage 402a is a logic inverter configured with ADG-FET devices ADG-PFET 401 and ADG-NFET 403. Inverting stages 402b-402e are configured like inverting stage 402a. Inverting stages 402a-402e are configured as a 5-stage ring oscillator with output 408 (from 402e) coupled back to the input 409 of inverting stage 402a. Voltage Vc_b 412 is coupled to all the back gates of ADG-PFET devices (e.g., ADG-PFET 401) in inverting stages 402a-402e. Likewise, voltage Vc 411 is coupled to all the back gates of ADG-NFET (e.g., ADG-NFET 403) in inverting stages 402a-402e. When Vc 411 increases and amount delta V, then Vc_b 4122 decreases by a like amount delta V. In this manner, both ADG-PFET 401 and ADG-NFET 403 are “enhanced” to conduct more current than would be dictated by the voltage on the front gates of ADG-PFET 401 and ADG-NFET 403. The conductivity of ADG-PFET 401 and ADG-NFET 403 is minimum when Vc 501 is most negative and Vc_b 502 is most positive and the conductivity of ADG-PFET 401 and ADG-NFET 403 is maximum when Vc 501 is most positive and Vc_b 412 is most negative. As the drive current of inverting stages 402a-402e is increased, their corresponding speed increases and the frequency of VCO 400 increases, likewise as the drive current of inverting stages 402a-402e is decreased, their corresponding speed decreases and the frequency of VCO 400 decreases.

VCO 400 is a wide frequency range circuit that uses fewer ADG-FET devices than a conventional ring VCO implemented using standard single gated FET devices. The inverting stages of FIG. 4 are simple logic inverters, however, NAND or NOR gates may be used as the inverting stages implementing VCO 400 and are considered within the scope of the present invention. Other circuitry like quasi-latches with cross-coupled NAND like gates may be implemented using ADG-FET devices that enable a VCO with complementary outputs. In these implementations the ADG-FET devices are again modulated according to embodiments of the present invention to vary the speed of the inverting stages and thus the frequency of a VCO. The scope of the present invention in intended to cover all circuitry that employ ADG-FET devices to implement a ring VCO, wherein complementary voltages are applied to the back gates of the ADG-FET devices to vary the speed of the inverting stages.

FIG. 4B is a circuit block diagram of VCO 420 according to embodiments of the present invention. Exemplary inverting stage 402a is a logic inverter configured with ADG-FET devices ADG-PFET 401 and ADG-NFET 403. Inverting stages 402b-402e are configured like inverting stage 402a. Inverting stages 402a-402e are configured as an exemplary 5-stage ring oscillator (oscillators with a differing odd number of stages may be configured) with output 408 (from 402e) coupled back to the input 409 of inverting stage 402a. All the back gates of the ADG-PFET devices (e.g., ADG-PFET 401) in inverting stages 402a-402e are coupled back to their corresponding inputs (e.g., 404 of inverting stage 402a). In this embodiment only voltage Vc 411 is coupled to all the back gates of the ADG-NFETs (e.g., ADG-NFET 403) in inverting stages 402a-402e. When Vc 411 increases and amount delta V, then the ADG-NFETs are “enhanced” to conduct more current than would be dictated by the voltage on the front gates of ADG-NFET 403. The conductivity of exemplary ADG-PFET 401 is controlled by the logic state on input 409. The conductivity of exemplary ADG-NFET 403 is minimum when Vc 411 is most negative and is maximum when Vc 411 is most positive. As the drive current of the ADG-NFET devices in inverting stages 402a-402e is increased, their corresponding speed increases and the negative transition on the output of each stage is faster causing the frequency of VCO 420 to increase. The negative transition of each stage is converted to an un-modulated positive transition in the succeeding stage to correct for asymmetry in the oscillator waveform. Likewise, as the drive current of the ADG-NFET devices in inverting stages 402a-402e is decreased, their corresponding speed decreases and the frequency of VCO 420 decreases. One of the stages may have the back gates of both the ADG-NFET and the ADG-PFET tied to the input so the output of the stage has equal transition speeds on both of its positive and negative transitions and would be suitable for generating a clock output.

FIG. 4C is a circuit block diagram of VCO 430 according to embodiments of the present invention. Exemplary inverting stage 402a is a logic inverter configured with ADG-FET devices ADG-PFET 401 and ADG-NFET 403. Inverting stages 402b-402e are configured like inverting stage 402a. Inverting stages 402a-402e are configured as a 5-stage ring oscillator with output 408 (from 402e) coupled back to the input 409 of inverting stage 402a. All the back gates of the ADG-NFET devices (e.g., ADG-PFET 403) in inverting stages 402a-402e are coupled back to their corresponding inputs (e.g., 404 of inverting stage 402a). In this embodiment only voltage Vc_b 412 is coupled to all the back gates of the ADG-PFETs (e.g., ADG-NFET 401) in inverting stages 402a-402e. When Vc_b 412 increases and amount delta V, then the ADG-PFETs are “enhanced” to conduct more current than would be dictated by the voltage on the front gates of ADG-PET 401 The conductivity of exemplary ADG-NFET 403 controlled by the logic state on input 409. The conductivity of exemplary ADG-PFET 401 is minimum when Vc_b 412 is most positive and is maximum when Vc_b 412 is most negative. As the drive current of the ADG-PFET devices in inverting stages 402a-402e is increased, their corresponding speed increases and the positive transition on the output of each stage is faster causing the frequency of VCO 430 to increase. The positive transition of each stage is converted to an un-modulated negative transition in the succeeding stage to correct for asymmetry in the oscillator waveform. Likewise, as the drive current of the ADG-PFET devices in inverting stages 402a-402e is decreased, their corresponding speed decreases and the frequency of VCO 430 decreases. One of the stages may have the back gates of both the ADG-NFET and the ADG-PFET tied to the input so the output of the stage has equal transition speeds on both of its positive and negative transitions and would be suitable for generating a clock output.

FIG. 4D is a circuit diagram of a ring VCO 451 implemented using DG-ND logic gates 451a-451e. DG-ND 451a gate is shown at device level to illustrate it has the same configuration as the DG-ND 370 gate shown in FIG. 3C. The second logic input of DG-ND logic gates 451a-451e may be coupled to a gate input 458. Ring VCO 450 is gated ON when gate input 458 is a logic one and OFF when gate input 458 is a logic zero. Complementary control voltages Vc_b 456 and Vc 457 are used to modulate the drive current and thus the speed of the ADG-FET devices implementing DG-ND logic gates 451a-451e. While the circuit of ring VCO 450 requires more devices it illustrates that a ring VCO may be implemented with inverting stages more complicated than an inverter.

FIG. 4E is a circuit diagram of a ring VCO 470 implemented using DG-NR logic gates 471a-471e. DG-ND 471a gate is shown at device level to illustrate it has the same configuration as the DG-NR 380 gate shown in FIG. 3D. The second logic input of DG-NR logic gates 471a-471e may be coupled to a gate input 478. Ring VCO 471 is gated ON when gate input 478 is a logic zero and OFF when gate input 478 is a logic one. Complementary control voltages Vc_b 456 and Vc 457 are used to modulate the drive current and thus the speed of the ADG-FET devices implementing DG-NR logic gates 471a-471e. The circuit of ring VCO 470 illustrates using another inverting stage more complicated than an inverter.

FIG. 4F is a circuit diagram of a ring VCO 480 implemented using DG-ND gates 481a-481e and 482a-482e. Each inverting stage is in a latch configuration wherein an output 492 and an in-phase complementary output 493 are generated. Like the circuits in FIG. 4A-4C, control voltages Vc_b 456 and Vc 457 are used to control the drive current and thus the speed of each of the inverting stages.

It is understood that the DG-ND logic gates and the DG-NR logic gates may have only the ADG-NFETs or the ADG-PFETs controlled by applying a control voltage to their corresponding back gates as illustrated in FIGS. 4B and 4C and still be within the scope of the present invention. Illustration of these embodiments was omitted to simplify the drawings and as they are not necessary to understand the scope of the present invention.

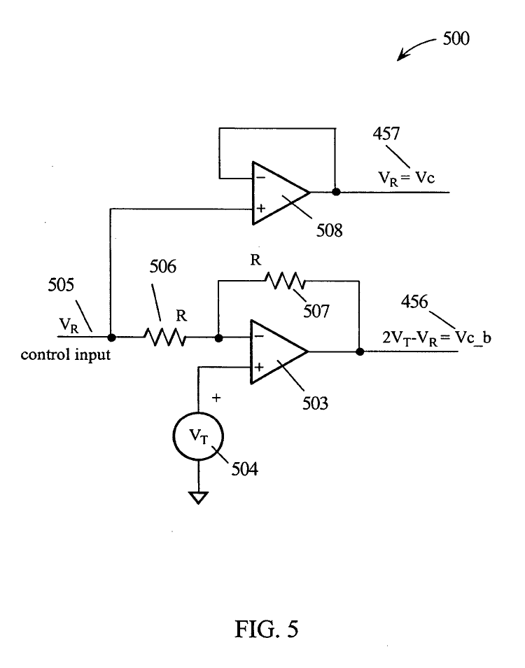

FIG. 5. is a circuit diagram of a circuit 500 suitable for generating a voltage Vc 457 and Vc_b 456 suitable for VCO 400 in FIG. 4. Vc 501 and Vc_b 502 have the same value when VR 505 is equal to off-set voltage VT 504. When VR 505 changes an amount delta V, then Vc 501 increases by delta V and Vc_b 502 decreases by delta V. Operational amplifier (OpAmp) 508 is configured as a non-inverting voltage follower and OpAmp 503 is configured as an inverting unit gain amplifier using resistors R506 and R507. OpAmp 503 is off-set by voltage VT 504. Other circuits may be used to generate Vc 457 and Vc_b 456 and are considered within the scope of the present invention.

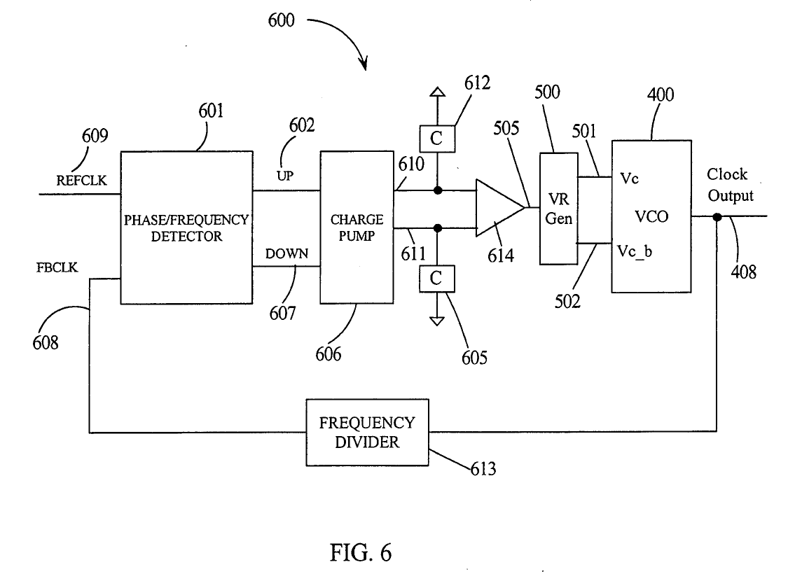

FIG. 6 is a block diagram of a representative phase lock loop circuit 600 suitable for practicing the principles of the present invention. Reference clock (RCLK) 609 and feedback clock (FBCLK) 608 are compared in phase/frequency detector (PFD) 601 generating UP signal 602 and DOWN signal 607 which are applied as control signals to charge pump 606. UP signal 602 and DOWN signal 607 are used to control current sources in charge pump 606. Charge pump 606 has charge pump nodes 610 and 611. Capacitor 612 is coupled between charge pump node 611 and ground and capacitor 605 is coupled between charge pump node 611 and ground. UP signal 602 and DOWN 607 are generated in response to a lead or lag phase difference between RCLK 609 and FBCLK 608. Since RCLK 609 and FBCLK 608 cannot concurrently have a lead and a lag phase error, UP signal 602 and DOWN 607 are mutually exclusive signals. Exemplary VCO 400 (See FIG. 4) produces a clock signal 408 according to embodiments of the present invention. Clock signal 408 is frequency divided by frequency divider 613 generating FBCLK 608. VCO 400 has voltage controlled frequency using the embodiment FIG. 7. The differential signal between charge pump nodes 610 and 611 is converted to an exemplary single ended control voltage 505 with amplifier 614. Reference generator VR 500 (see FIG. 5) is a block diagram of an exemplary circuit for generating Vc 457 and Vc_b 456 for control the frequency of VCO 400 within a frequency range. It is understood that ring VCOs as depicted in FIG. 4B-4D may also be used in the PLL and are considered within the scope of the present invention.

Although the circuitry and system are described in connection with several embodiments, it is not intended to be limited to the specific forms set forth herein, but on the contrary, it is intended to cover such alternatives, modifications and equivalents, as can be reasonably included within the spirit and scope of the invention as defined by the appended claims. It is noted that the headings are used only for organizational purposes and not meant to limit the scope of the description or claims.

What is claimed is:

1. A voltage controlled ring oscillator (VCO) comprising a first group of an odd number N inverting stages coupled in series with at least one of the N inverting stages having a logic input and a logic output and a first asymmetrical dual gated FET (ADG-FET) having a front gate coupled as the logic input, a drain terminal supplying drive current for the logic output, a back gate coupled to a first control voltage and a source terminal coupled to receive current from a first voltage potential of a power supply, wherein a level of the drive current is varied in response to the first control voltage to vary a frequency of the VCO.

2. The VCO of claim 1, wherein the at least one of the N inverting stages further comprises a second ADG-FET having a drain terminal supplying drive current for the logic output, a source terminal coupled to deliver drive current to a second voltage potential of the power supply, a front gate coupled to the logic input, and a back gate coupled to a second control voltage, wherein a level of the drive current is varied in response to the second control voltage to vary a frequency of the VCO.

3. The VCO of claim 2, wherein the first ADG-FET is a dual gated asymmetrical P-channel FET (ADG-PFET), the second ADG-FET is a dual gated asymmetrical N-channel FET (ADG-NFET) and each of the N inverting stages is configured as a complementary metal oxide semiconductor (CMOS) inverter stage.

4. The VCO of claim 2, wherein each of the first group of N inverting stages further comprises a second logic input and a third ADG-FET with a front gate coupled to the second logic input, a drain terminal supplying drive current for the logic output, a back gate coupled to a first control voltage and a source terminal coupled to receive the drive current from the first voltage potential of the power supply, wherein a level of the drive current is varied in response to the first control voltage to vary a frequency of the VCO.

5. The VCO of claim 4, wherein each of the first group of N inverting stages further comprises a fourth ADG-FET with a drain terminal supplying drive current for the logic output, a source terminal coupled to deliver drive current to the second voltage potential of the power supply, a front gate coupled to the second logic input, and a back gate coupled to the second control voltage, wherein a level of the drive current is varied in response to the second control voltage to vary a frequency of the VCO.

6. The VCO of claim 5 wherein the third ADG-FET is an ADG-PFET and the fourth ADG-FET is an ADG-NFET.

7. The VCO of claim 6, wherein the second logic inputs of the first group of N inverting stages are coupled to a gating logic signal and each of the N inverting stages is configured as a NAND gate.

8. The VCO of claim 6, wherein the second logic inputs of the first group N inverting stages are coupled to a gating logic signal and each of the N inverting stages is configured as a NOR gate.

9. The VCO of claim 6, further comprising a second group of the odd number N inverting stages series connected, with a logic output of stage K (modulo N) of the first group of N inverting stages coupled to the second input of stage K (modulo N) of the second group of N inverting stages and to the first input of stage K+1 (modulo N) of the first group of N inverting stages and with a logic output of stage K (modulo N) of the second group of N inverting stages is coupled to the second input of stage K of the first group of N inverting stages and to the first input of stage K+1 (modulo N) of the second group of N inverting stages, wherein the output of stage N of the first group of N inverting stages generates a first output signal and the output of stage N of the second group of N inverting stages generates an in-phase complement of the first output signal.

10. The VCO of claim 3, wherein the first ADG-PFET has P+ polysilicon for the front gate and N+ polysilicon for the back gate and the second ADG-NFET has N+ polysilicon for the front gate and P+ polysilicon for the back gate.

11. The VCO of claim 6, wherein the third ADG-PFET has P+ polysilicon for the front gate and N+ polysilicon for the back gate and the fourth ADG-DG-NFET has N+ polysilicon for the front gate and P+ polysilicon for the back gate

12. The VCO of claim 2, wherein the first and second control voltages are complementary relative to an off-set voltage level.

13. A phase locked loop (PLL) circuit for generating a clock signal and a substantially non-skewed complementary clock signal of the same frequency that is a multiple number P times the frequency of a reference clock signal, comprising:
a voltage controlled oscillator (VCO) generating the clock signal with a frequency modified in response to a control voltage;
a frequency divider for frequency dividing the clock signal or the complementary clock signal by P, generating a frequency divided clock signal;
a phase frequency detector for comparing the frequency divided clock signal to the reference clock signal and generating a phase/frequency error signal; and
circuitry for converting the phase/frequency error signal to the control voltage, wherein the VCO has a first group of an odd number N inverting stages coupled in series with at least one of the N inverting stages having a logic input and a logic output and a first asymmetrical dual gated FET (ADG-FET) having a front gate coupled as the logic input, a drain terminal supplying drive current for the logic output, a back gate coupled to a first control voltage and a source terminal coupled to receive current from a first voltage potential of a power supply, wherein a level of the drive current is varied in response to the first control voltage to vary a frequency of the VCO.

14. The PLL of claim 13, wherein the at least one of the N inverting stages further comprises a second ADG-FET having a drain terminal supplying drive current for the logic output, a source terminal coupled to deliver drive current to a second voltage potential of the power supply, a front gate coupled to the logic input, and a back gate coupled to a second control voltage, wherein a level of the drive current is varied in response to the second control voltage to vary a frequency of the VCO.

15. The PLL of claim 14, wherein the first ADG-FET is a dual gated asymmetrical P-channel FET (ADG-PFET), the second ADG-FET is a dual gated asymmetrical N-channel FET (ADG-NFET) and each of the N inverting stages is configured as a complementary metal oxide semiconductor (CMOS) inverter stage.

16. The PLL of claim 14, wherein each of the first group of N inverting stages further comprises a second logic input and a third ADG-FET with a front gate coupled to the second logic input, a drain terminal supplying drive current for the logic output, a back gate coupled to a first control voltage and a source terminal coupled to receive the drive current from the first voltage potential of the power supply, wherein a level of the drive current is varied in response to the first control voltage to vary a frequency of the VCO.

17. The PLL of claim 16, wherein each of the first group of N inverting stages further comprises a fourth ADG-FET with a drain terminal supplying drive current for the logic output, a source terminal coupled to deliver drive current to the second voltage potential of the power supply, a front gate coupled to the second logic input, and a back gate coupled to the second control voltage, wherein a level of the drive current is varied in response to the second control voltage to vary a frequency of the VCO.

18. The PLL of claim 17 wherein the third ADG-FET is an ADG-PFET and the fourth ADG-FET is an ADG-NFET.

19. The PLL of claim 18, wherein the second logic inputs of the first group of N inverting stages are coupled to a gating logic signal and each of the N inverting stages is configured as a NAND gate.

20. The PLL of claim 18, wherein the second logic inputs of the first group N inverting stages are coupled to a gating logic signal and each of the N inverting stages is configured as a NOR gate.

21. The PLL of claim 18, further comprising a second group of the odd number N inverting stages series connected, with a logic output of stage K (modulo N) of the first group of N inverting stages coupled to the second input of stage K (modulo N) of the second group of N inverting stages and to the first input of stage K+1 (modulo N) of the first group of N inverting stages and with a logic output of stage K (modulo N) of the second group of N inverting stages is coupled to the second input of stage K of the first group of N inverting stages and to the first input of stage K+1 (modulo N) of the second group of N inverting stages, wherein the output of stage N of the first group of N inverting stages generates a first output signal and the output of stage N of the second group of N inverting stages generates an in-phase complement of the first output signal.

22. The PLL of claim 15, wherein the first ADG-PFET has P+ polysilicon for the front gate and N+ polysilicon for the back gate and the second ADG-NFET has N+ polysilicon for the front gate and P+ polysilicon for the back gate.

23. The PLL of claim 18, wherein the third ADG-PFET has P+ polysilicon for the front gate and N+ polysilicon for the back gate and the fourth ADG-DG-NFET has N+ polysilicon for the front gate and P+ polysilicon for the back gate

24. The PLL of claim 14, wherein the first and second control voltages are complementary relative to an off-set voltage level.
